(19) United States
(12) Patent Application Publication
(10) Pub. No.: US 2009/0096548 A1
(43) Pub. Date: Apr. 16, 2009

(54) Tuning and compensation technique for semiconductor bulk resonators

(76) Inventor: Peter J. Hopper, San Jose, CA (US)

Correspondence Address: STALLMAN & POLLOCK LLP, 353 SACRAMENTO STREET, SUITE 2200, SAN FRANCISCO, CA, 94111, US

(21) Appl. No.: 11/974,301

(22) Filed: Oct. 12, 2007

(51) Int. Cl. H03H 9/24

(52) U.S. Cl. 333/186

(57) ABSTRACT

One or more pn junctions are provided on the resonating bar of a semiconductor bulk resonator. When a reverse bias is imposed upon the pn junction(s), a variable depletion layer results and, hence, capacitance. The depletion layer capacitance allows for variable coupling to the resonator bar. The variable coupling allows control circuitry to null out or compensate for variation related to temperature and/or drift.

### FIELD OF THE INVENTION

The present invention relates to integrated circuits and, in particular, to an electrostatic compensation technique for tuning a bulk resonator to compensate for the effects of temperature and/or drift.

### DISCUSSION OF THE RELATED ART

Bulk acoustic wave resonators (FBAR) and are increasingly utilized in RF integrated circuit applications because of their high quality (Q) factor.

U.S. Pat. No. 7,176,770, titled “Capacitive Vertical Silicon Bulk Acoustic Resonator” and which issued to the Georgia Tech Research Corp. on Feb. 13, 2007, discloses a number of embodiments of a capacitive vertical silicon bulk acoustic resonator (SiBAR) that operate in the HF/VHF/UHF bands, exhibit low impedance values and have relatively high Q factors.

FIG. 1 shows an embodiment of a SiBAR 10 disclosed in the '770 patent. The SiBAR 10 comprises a silicon substrate 11 that includes one or more bias pads 12 that are separated from an elongated portion of the silicon substrate 11. The elongated portion of the silicon substrate 11 comprises a crystalline silicon resonating bar 15. The resonating bar 15 is connected to the bias pads 12 by one or more silicon bridge portions or support beams 16 that are disposed at respective ends of the resonating bar 15. The bias pads 12 form anchors in or to the substrate 11 that allows the resonating bar 15 to be suspended between the support beams 16. Electrodes 14, which may comprise polysilicon, for example, are disposed on adjacent sides of the resonating bar 15 and are separated from the resonating bar 15 by capacitive gaps 13. The capacitive gaps 13 may comprise air gaps, or may be filled with a fluid material. The resonating bar 15 is separated from adjacent edges of the respective electrodes 14 by openings 17, such as air gaps. By application of a bias voltage Vbias to the bias pads 12, a desired resonant frequency is obtained by proper selection of the physical design parameters for the resonator 10.

As is well known, bulk silicon resonators are sensitive to temperature. Thus, as further shown in FIG. 1, the resonator 10 disclosed in the '770 patent includes a tuning current generator 21 that couples current to the resonating bar 15 by way of the bias pads 12 to heat the resonator membrane 15 by resistive heating. This functions to null out the effect of temperature and/or drift.

U.S. Pat. No. 7,176,770 is hereby incorporated by reference herein in its entirety to provide background information regarding the present invention.

While the tuning mechanism proposed in the '770 patent, i.e. tuning the resonator by forcing a current through the resonating bar 15 to resistively heat the bar, is an effective tuning mechanism, the current and related joule heating requires a considerable power budget. Thus, it would be highly desirable to have available a low power method of addressing temperature instability in bulk resonators.

### SUMMARY OF THE INVENTION

The present invention provides an electrostatic technique for compensating for temperature and/or drift in semiconductor bulk resonators. In accordance with the invention, one or more pn junctions are provided within the resonating bar whereby, when a reverse bias is imposed upon the pn junction(s), a variable depletion layer thickness results and, therefore, capacitance. The depletion layer capacitance allows for variable coupling to the resonating bar. This variable coupling allows for control circuitry to null out variation related to temperature and/or drift.

The features and advantages of the various aspects of the present invention will be more fully understood and appreciated upon consideration of the following detailed description of the invention and the accompanying drawings, which set forth an illustrative embodiment in which the concepts of the invention are utilized.

### DESCRIPTION OF THE DRAWINGS

FIG. 1 illustrates a known embodiment of a capacitive silicon bulk acoustic wave resonator (SiBAR).

FIG. 2 is a plan view of a bulk silicon resonating bar in accordance with the concepts of the present invention.

FIG. 3 is a plan view of a bulk silicon resonating bar with multi-mode tuning in accordance with the concepts of the present invention.

### DETAILED DESCRIPTION OF THE INVENTION

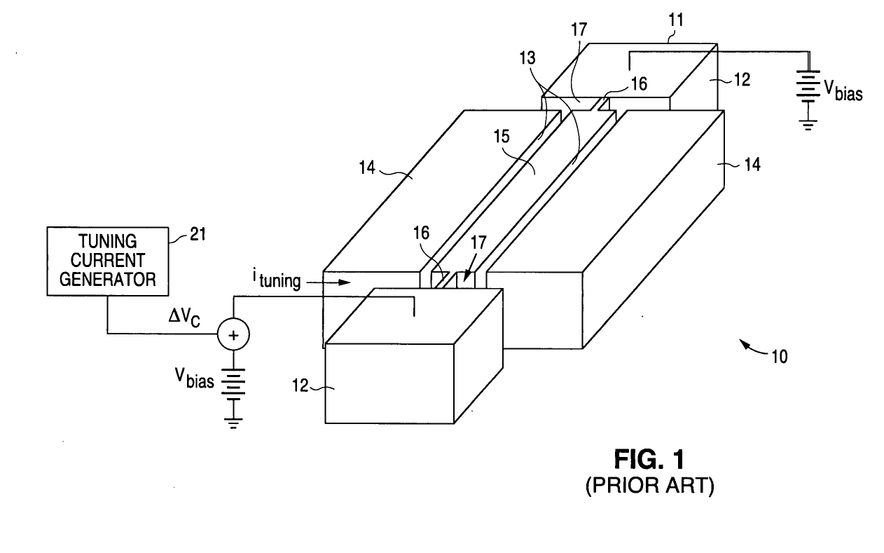

The present invention provides an electrostatic technique for compensating for temperature and/or drift in silicon resonators of the type discussed above in conjunction with FIG. 1. Those skilled in the art will appreciate that the concepts of the present invention are not limited to the FIG. 1 silicon resonator design but are more widely applicable to a variety of silicon resonator architectures. In general, in accordance with the invention, a pn junction is provided within the resonating bar of a semiconductor bulk resonator whereby, when a reverse bias is imposed upon the pn junction, a variable depletion layer thickness results and, hence, capacitance. The depletion layer capacitance allows for variable coupling to the resonating bar. This variable coupling allows for control circuitry to null out variation related to temperature and/or drift.

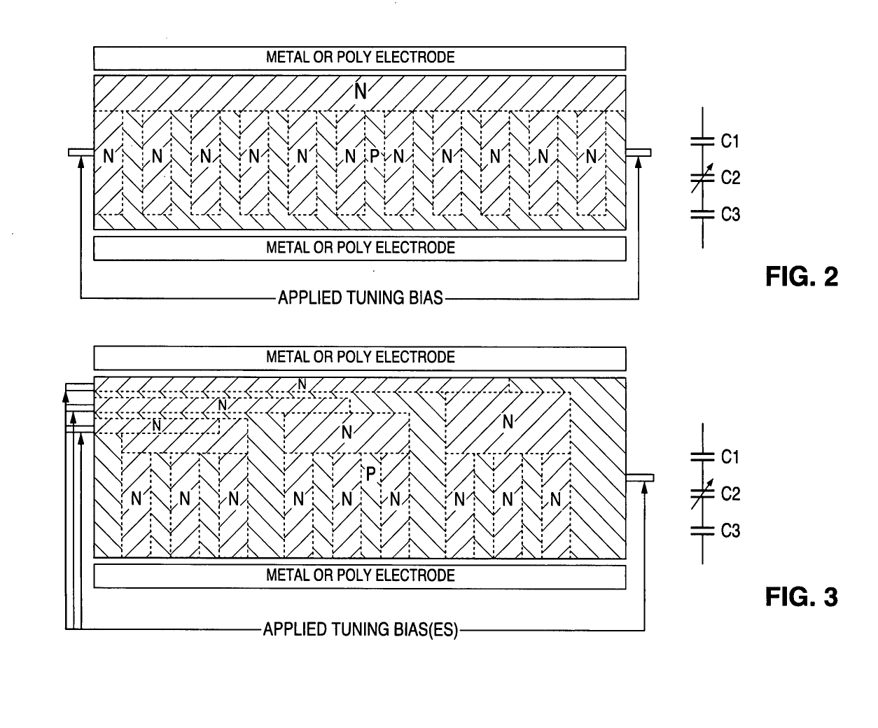

FIG. 2 shows a resonating bar 200 that includes a layout of fingered pn junctions that is designed to provide variable coupling to the metal electrodes as a function of applied bias. FIG. 3 shows a resonating bar 300 that includes a layout of independent doping junction islands within the resonating bar. The FIG. 3 design allows for higher order tuning to occur via a set of independent electrodes. This more flexible tuning approach allows for multi-mode tuning, the ability to tune differently along the length of the resonating bar.

Those skilled in the art will appreciate that the FIG. 2 membrane design and the FIG. 3 membrane design can be substituted for the resonator membrane 15 of the FIG. 1 SiBAR 10 to provide a bulk silicon resonator design in accordance with the concepts of the present invention.

FIG. 2 shows an embodiment of the invention that includes an elongated crystalline silicon resonating bar 200 of p-type conductivity. A diffusion region 202 of n-type conductivity is formed in the resonating bar 200 and includes a plurality of spaced-apart n-type fingers 204 that define a plurality of pn junctions in the resonating bar 200. Those skilled in the art will appreciate that the ends of the resonating bar may be attached to respective bias pads in the manner discussed above in conjunction with FIG. 1. FIG. 2 also shows two metal or polysilicon electrodes 206 that are disposed adjacent to and spaced-apart from the resonating bar 200. Bias circuitry (not shown) is connected to the bias pads to provide a bias voltage to the resonating bar 200. Tuning control circuitry applies a tuning bias voltage to the resonating bar 200 to compensate for the effects of temperature and/or drift, as discussed above.

FIG. 3 shows an alternate embodiment of the invention that includes an elongated crystalline silicon resonating bar 300 of p-type conductivity. A plurality of distinct n-type diffusion regions (e.g., regions 302, 304 and 306 in FIG. 3) are formed in the resonating bar 300. Each distinct n-type region includes a plurality of spaced-apart n-type fingers (302a, 304a and 306a in FIG. 3) that define a plurality of pn junctions in that diffusion region. Tuning control circuitry coupled to the resonating bar 300 applies a separate tuning voltage to each of the plurality of diffusion regions. As in the case of the FIG. 2 embodiment, the ends of the resonating bar 300 may be attached to respective bias pads to which a bias voltage is applied to obtain the desired resonant frequency. As shown in FIG. 3, metal or polysilicon electrodes 308 are disposed adjacent to and space-apart from the sides of the resonating bar 300 in the well known manner. As discussed above, the FIG. 3 embodiment of the invention provides a more flexible tuning approach that allows for different tuning along the length of the resonating bar 300.

It should be understood that the particular embodiments of the invention described above have been provided by way of example and that other modifications may occur to those skilled in the art without departing from the scope and spirit of the invention as express in the appended claims and their equivalents.

What is claimed is:

1. A resonating bar of a semiconductor bulk resonator, the resonating bar comprising:
an elongated semiconductor member having a first conductivity type;
one or more regions having a conductivity type opposite the first conductivity type formed in the elongated semiconductor member.

2. A resonating bar as in claim 1, and wherein the first conductivity type is p-type and the second conductivity type is n-type such that the one or more n-type regions formed in the p-type elongated semiconductor member define one or more pn junctions.

3. A resonating bar as in claim 1, and wherein the elongated semiconductor member comprises crystalline silicon.

4. A resonating bar as in claim 1, and wherein the one or more regions comprise two or more tuning regions, each tuning region having a plurality of spaced-apart diffusion regions having the second conductivity type formed therein to define a plurality of junctions in said tuning region.

5. A resonating bar as in claim 4, and wherein the first conductivity type is p-type and the second conductivity type is n-type.

6. A silicon bulk resonator comprising:
an elongated resonating bar having first and second ends respectively connected to first and second bias pads, the resonating bar comprising a crystalline silicon member having a first conductivity type and a plurality of spaced-apart regions having a second conductivity type opposite the first conductivity type formed in the crystalline silicon member to define a plurality of junctions in the resonating bar;
a first electrode disposed on a first side of the resonating bar and spaced-part therefrom;
a second electrode disposed on a second side of the resonating bar and spaced-apart therefrom;
bias circuitry connected to the first and second bias pads to provide a bias voltage to the resonating bar; and
tuning control circuitry coupled to the resonating bar to apply a tuning voltage thereto.

7. A silicon bulk resonator as in claim 6, and wherein the first conductivity type is p-type and the second conductivity type is n-type.

8. A silicon bulk resonator comprising:
an elongated resonating bar having first and second ends respectively connected to first and second bias pads, the resonating bar comprising a crystalline silicon member having a first conductivity type and two or more tuning regions, each tuning region having a plurality of spaced-apart regions having a second conductivity type opposite the first conductivity type formed therein to define a plurality of junctions in said tuning region;
a first electrode disposed on a first side of the resonating bar and spaced-apart therefrom;
a second electrode disposed on a second side of the resonating bar and spaced-apart therefrom;
bias circuitry connected to the first and second bias pads to provide a bias voltage to the resonating bar; and
tuning control circuitry coupled to the resonating bar to apply a separate tuning voltage to each of the tuning regions.

9. A silicon bulk resonator as in claim 8, and wherein the first conductivity type is p-type and the second conductivity is n-type.
